(19) United States
(12) Patent Application Publication
(10) Pub. No.: US 2015/0084013 A1
(43) Pub. Date: Mar. 26, 2015

(54) ORGANIC SEMICONDUCTOR ELEMENT AND CMIS SEMICONDUCTOR DEVICE INCLUDING THE SAME

(71) Applicant: Tadahiro Ohmi, Sendai-shi (JP)

(72) Inventor: Tadahiro Ohmi, Sendai-shi (JP)

(73) Assignee: TOHOKU UNIVERSITY, Sendai-shi (JP)

(21) Appl. No.: 14/306,591

(22) Filed: Jun. 17, 2014

Related U.S. Application Data
(63) Continuation of application No. PCT/JP2013/005740, filed on Sep. 26, 2013.

(51) Int. Cl. H01L 51/05

(52) U.S. Cl. CPC H01L 51/0512
USPC 257/40

(57) ABSTRACT

There is provided with an organic semiconductor element. The organic semiconductor element has a source electrode portion, a drain electrode portion, an active layer region of an organic semiconductor, a gate insulating film, and a gate electrode portion. The source electrode portion has a multilayer structure where layers are arranged in order of a work function from a lowermost layer region in contact with the active layer region to an uppermost layer region. A work function of a material of the lowermost layer region is closer to a work function of a material of the active layer region than a work function of a material of the uppermost layer region. The lowermost region is made of lanthanum boride (LaB₆) and contains nitrogen.

This application is a continuation of International Patent Application No. PCT/JP2013/005740 filed on Sep. 26, 2013, the entire content of which is incorporated herein by reference.

### BACKGROUND OF THE INVENTION

1. Field of the Invention

The present invention relates to an organic semiconductor element and a CMIS semiconductor device including the same.

2. Description of the Related Art

Organic semiconductors are generally more advantageous than silicon single crystal semiconductors in flexibility, lightweight properties, shock resistance, thin film formability, cost reduction, and area increase except carrier mobility. Especially as for the area cost, the larger the area is, the more conspicuous the advantage is. For this reason, the organic semiconductors are suitable for large-area electronic devices such as a selfluminous display device and a solar cell, and industry expectations are rising.

On the other hand, although some organic semiconductors achieve hole mobility to some extent, most organic semiconductors are single crystal materials and the area increasing capability (a number of thin film transistors (to be also referred to as “TFTs” hereinafter) formed over a large area) that is a feature of organic semiconductors cannot fully be exploited.

Additionally, most organic semiconductors are neither n- nor p-type but intrinsic (i-type) semiconductors or materials close to those. More specifically, unlike general inorganic semiconductors such as silicon (Si) which are susceptible to impurity doping to change themselves into n- or p-type semiconductors and perform an n- or p-type semiconductor operation, an organic semiconductor is caused to perform an n- or p-type operation in actuality by controlling the interface between an electrode and the organic semiconductor and the interface between an insulator and the organic semiconductor. This is because n- and p-type organic semiconductors that allow efficient doping and are usable for practical applications, like inorganic semiconductors, have not been implemented yet.

To cause an organic semiconductor to perform an n- or p-type operation, the following methods are probably usable and have partially been implemented on the laboratory level. More specifically, to perform a p-type operation, an electrode is formed using a material with a large work function to ensure matching with the HOMO (Highest Occupied Molecular Orbital) of a selected organic semiconductor material as much as possible, thereby facilitating hole injection to the HOMO of the organic semiconductor material. To perform an n-type operation, an electrode is formed using a material with a small work function to ensure matching with the LUMO (Lowest Unoccupied Molecular Orbital) of a selected organic semiconductor material as much as possible, thereby facilitating electron injection to the LUMO of the organic semiconductor material.

However, as for thin film (amorphous, polycrystalline, microcrystalline) materials suitable for increasing the area, the reality generally shows that there exists no material stably having mobility sufficient for practical use (instead of increasing mobility itself, carriers are injected from an electrode with a sufficient density and thus sufficiently stored in a carrier storage layer, thereby obtaining apparently high mobility) for an n-type operation, as compared to materials having conduction characteristics for a p-type operation. Needless to say, there is no bipolar material having both electron mobility and hole mobility suitable for practical applications at all. For these reasons, to form a semiconductor device having a CMIS circuit arrangement represented by a CMOS circuit arrangement, different materials need to be selected for p- and n-types. This leads to an increase in man-hour in addition to complex manufacturing processes, resulting in lower production efficiency and high cost.

Pentacene that is one of bipolar organic semiconductors is a material especially regarded as promising. As for carrier mobility, pentacene has hole mobility of about 0.1 to 1 m/Vsec equivalent to amorphous silicon (to be also abbreviated as “A-Si” hereinafter). However, electron mobility is as small as about 0.05 m/Vsec. For this reason, when pentacene is applied to a CMOS semiconductor device with excellent power consumption, extreme characteristic mismatching occurs between a pMOS transistor (to be also referred to as “pMOS Tr” hereinafter) and an nMOS transistor (to be also referred to as “nMOS Tr” hereinafter). It is therefore impossible to make full use of the merits of the organic semiconductor.

As a solution to this problem, it has been reported that a metal layer of Ca (calcium) (2.8 eV) or the like having a small work function is introduced as an electron supply layer into the interface between a gate insulating film and an active layer region made of pentacene to improve the apparent electron mobility (in fact, a current flowing through the active region from the source side to the drain side is increased), thereby improving the n-type operation characteristic of pentacene (Japanese Journal of Applied Physics 51 (2012) 04DK01: NPL 1).

### SUMMARY OF THE INVENTION

According to an embodiment of the invention, an organic semiconductor element comprises: a source electrode portion; a drain electrode portion; an active layer region of an organic semiconductor; a gate insulating film; and a gate electrode portion, wherein the source electrode portion has a multilayer structure where layers are arranged in order of a work function from a lowermost layer region in contact with said active layer region to an uppermost layer region so that a work function of a material of the lowermost layer region is closer to a work function of a material of the active layer region than a work function of a material of the uppermost layer region, and the lowermost region is made of lanthanum boride (LaB₆) and contains nitrogen.

According to another embodiment of the invention, an organic semiconductor element comprises: a source electrode portion; a drain electrode portion; an active layer region of an organic semiconductor wherein the organic semiconductor is pentacene; a gate insulating film; a gate electrode portion; and a layer region that is in contact with the active layer region and contains lanthanum boride (LaB₆) on a side close to the gate insulating film, wherein the source electrode portion has a multilayer structure where layers are arranged in order of a work function from a lowermost layer region in contact with said active layer region to an uppermost layer region so that a work function of a material of the lowermost layer region is closer to a work function of a material of the active layer region than a work function of a material of the uppermost layer region.

According to still another embodiment of the invention, an organic semiconductor element comprises: a source electrode portion; a drain electrode portion; an active layer region of an organic semiconductor; a gate insulating film; and a gate electrode portion, wherein the source electrode portion has a multilayer structure where layers are arranged in order of a work function from a lowermost layer region in contact with said active layer region to an uppermost layer region so that a work function of a material of the lowermost layer region is closer to a work function of a material of the active layer region than a work function of a material of the uppermost layer region, the lowermost layer region is made of lanthanum boride (LaB₆) and nitrogen is added to the lanthanum boride (LaB₆), and the organic semiconductor exhibits a p-type operation characteristic.

Other features and advantages of the present invention will be apparent from the following descriptions taken in conjunction with the accompanying drawings, in which like reference characters designate the same or similar parts throughout the figures thereof.

### BRIEF DESCRIPTION OF THE DRAWINGS

The accompanying drawings, which are incorporated in and constitute a part of the specification, illustrate embodiments of the invention and, together with the description, serve to explain the principles of the invention.

FIG. 1 is a schematic structural explanatory view for explaining the structure of an nMOS Tr as one of examples of preferable embodiments of the present invention;

FIG. 2 is a schematic structural explanatory view for explaining the structure of a semiconductor device having a CMOS circuit structure as one of examples of preferable embodiments of the present invention; and

FIG. 3 is a circuit diagram of the semiconductor device shown in FIG. 2.

### DESCRIPTION OF THE EMBODIMENTS

Metals such as Ca readily oxidize, and problems exist in the device operation characteristic and the production efficiency and mass productivity of device manufacture. In particular, calcium (Ca) reacts with oxygen, water, and carbon dioxide and corrodes when left to stand in air, and especially reacts vigorously with water to generate hydrogen, or directly reacts with halogen in a vapor phase to generate a halogen compound. Because of this high chemical reactivity, handling of calcium in a production line tends to be cumbersome.

An embodiments has been made by extensive studies in consideration of the above-described problems, and improves the n-type operation characteristic of an organic semiconductor element.

An embodiments also improves the n-type operation characteristic of pentacene and provides an organic semiconductor element having an n-type operation characteristic equal to or better than a p-type operation electronic element using pentacene and a semiconductor device having a CMIS circuit arrangement and, more particularly, a CMOS circuit arrangement including the element as a constituent electronic element.

According to an embodiment, it is possible to obtain an organic semiconductor element and a CMIS semiconductor device which have a high device operation characteristic, excellent operation stability, and high production efficiency of device manufacture and are suitable for mass production. Additionally, according to an embodiment, it is possible to obtain an organic semiconductor element and a CMIS semiconductor device which can be driven by a low voltage at a high speed.

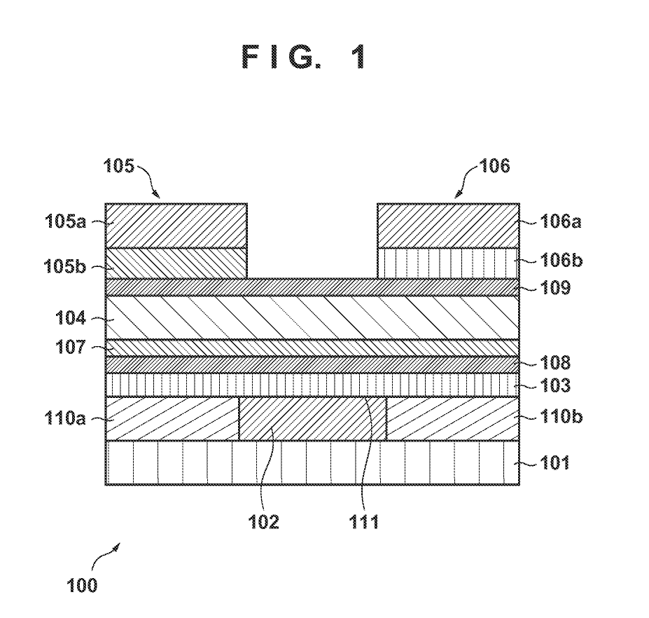

FIG. 1 is a schematic structural explanatory view for explaining the structure of an nMOS Tr as one of preferable embodiments of the present invention.

An nMOS Tr 100 shown in FIG. 1 exhibits an n-type conduction characteristic, and has a stacked structure in which a gate electrode 102, a gate insulating film 103, an active layer region 104 of an organic semiconductor (preferably, pentacene), and a source electrode region 105 and a drain electrode region 106 are overlaid on a substrate 101 in this order. As a characteristic feature, a layer region (A) 107 containing lanthanum boride (to be also referred to as “LaB₆” hereinafter) is provided in contact with the active layer region 104 while being sandwiched between the active layer region 104 and the gate insulating film 103. In the present invention, the layer region (A) 107 is provided as needed as an example of preferable embodiments but is not an essential component of the present invention.

The layer region (A) 107 has a function of supplying electrons to the active layer region 104 to increase the mobility of the active layer region 104 when the nMOS Tr 100 operates. That is, the layer region (A) 107 functions as an electron supply layer. Lanthanum boride (LaB₆) is a material having a small work function by itself. However, the work function can be made smaller by adding nitrogen (N) in the manufacturing process of the active layer region 104.

The nMOS Tr 100 shown in FIG. 1 has the above-described structure as a basic structure. If necessary, a first interface control layer 108 is further provided between the gate insulating film 103 and the layer region (A) 107 in accordance with the purpose. Additionally, in the source electrode portion 105 and the drain electrode portion 106, a second interface control layer 109 is provided on the side of the active layer region 104 while being in direct contact with the active layer region 104. The interface control layer 108 is provided as needed to improve the interface characteristic between the gate insulating film 103 and the active layer region 104 (especially to improve suppression of interface level occurrence).

The interface control layers 108 and 109 are preferably made of a heat-resistant material in consideration of process temperatures in subsequent manufacturing processes. An example of the material preferably employed in the present invention is polyvinyl phenol (to be also abbreviated as “PVPh” hereinafter).

The characteristic of the interface between the gate insulating film 103 and the active layer region 104 affects especially stabilization of the threshold voltage of the nMOS Tr 100. The threshold voltage can be stabilized by providing the interface control layer 108. In particular, when formed by vapor deposition of PVPh, the interface control layer 108 can be made very thin without pinholes, greatly stabilizing the threshold voltage and reducing the operation voltage.

The interface control layer 109 is provided as needed to improve the interface characteristic between the active layer region 104 and the source electrode portion 105/drain electrode portion 106. Especially, when the interface control layer 109 is made of vapor deposition-oriented PVPh, the interface level that causes carrier trap can largely be reduced. Hence, the setting of the interface control layer 109 of PVPh is preferable in the present invention. The interface control layer 109 is also preferably made of a heat-resistant material in consideration of process temperatures in subsequent manufacturing processes, like the interface control layer 108.

Planarization regions 110 (110a, 110b) made of a resin or the like are provided around the gate electrode 102 formed on the substrate 101 to form surfaces flush with an upper surface 111 of the gate electrode 102 and provide the gate insulating film 103 on the gate electrode 102. If the planarization regions 110 are made of a resin, a heat-resistant resin is preferably used to easily apply high-temperature processing in subsequent processes.

In the present invention, various materials are usable for the substrate 101. Preferably employable materials are heat-resistant plastics, glass, metals, ceramics, and the like. Examples of the materials are quartz, soda lime glass, alkali metalless glass, silicon substrates, metal substrates made of aluminum, stainless steel, and the like, semiconductor substrates such as a gallium arsenide (GaAs) substrate, and thermoplastic and thermosetting plastic substrates. If not so high heat resistance is required (process temperature: 200° C. or less), for example, polyolefins such as such as polyethylene, polypropylene, ethylene-propylene copolymer, and ethylene-vinyl acetate copolymer (EVA), cyclic polyolefin, modified polyolefin, polyvinyl chloride, polyvinylidene chloride, polystyrene, polyamide, polyimide, polyamide imide, polycarbonate, poly(4-methylpentene-1), ionomer, acrylic resins, polymethyl methacrylate, acryl-styrene copolymer (AS resin), butadiene-styrene copolymer, polio copolymer (EVOH), polyesters such as polyethylene terephthalate, polybutylene terephthalate, polyethylene naphthalate, and polycyclohexane terephthalate (PCT), polyether, polyether ketone, polyether ether ketone, polyetherimide, polyacetal, polyphenylene oxide, modified polyphenylene oxide, polyalylate, aromatic polyester (liquid crystal polymer), polytetrafluoroethylene, polyvinylidene fluoride, other fluororesins, various kinds of thermoplastic elastomers such as styrene-based copolymer, polyolefin-based, polyvinyl chloride-based, polyurethane-based, fluororubber-based, and chlorinated polyethylene-based thermoplastic elastomers, epoxy resins, phenol resins, urea resins, melamine resins, unsaturated polyester resins, silicone resins, polyurethane resins, and copolymers, blends, and polymer alloys mainly containing them are usable as the material of a plastic substrate. A substrate having a composite stacked structure formed by stacking two or more of the above-described materials is also usable.

As the electrode material of the gate electrode 102, most materials normally used in the semiconductor field can be employed.

In a bottom gate type field effect transistor (to be also referred to as “FET” hereinafter) as shown in FIG. 1, the substrate 101 is required to have heat resistance to some extent or more. Hence, the material is selected in accordance with the desired heat resistance in design.

In the present invention, the electrode material of the gate electrode 102 is preferably selected from following conductive materials. The conductive materials are, for example, metals such as Cr, Al, Ta, Mo, Nb, Cu, Ag, Au (4.9 eV), Pt, Pd, In, Ni, Nd, Ca, Ti, Ta, Ir, Ru, W, Mo, and an Ru—Mo alloy and alloys of these metals. Other examples are conductive oxides such as InO₂, SnO₂, and ITO, conductive nitrides such as TiN and TaN, conductive polymers such as polyaniline, polypyrrole, polythiophene, and polyacetylene, molecular conductors such as graphene, carbon nanotubes, and charge-transfer complexes, and stacked structure members thereof. A material obtained by adding a dopant, for example, an acid such as hydrochloric acid, sulfuric acid, or sulphonic acid, a Lewis acid such as PF₆, AsF₅, or FeCl₃, halogen atoms such as iodine, or metal atoms such as sodium or potassium to the conductive polymers may be used. A conductive composite material in which carbon black or metal particles are dispersed may be used.

The gate electrode 102 is preferably formed as thin as possible as long as an electrode function is obtained, and no pinholes are formed in consideration of the planarity of a layer (or film) to be formed on it. More specifically, the gate electrode 102 is normally formed to a thickness of 100 nm or less, preferably 50 nm or less, and more preferably 10 nm or less.

The planarization regions 110 are preferably made of a heat-resistant material. If not so high heat resistance is needed (process temperature: 200° C. or less), the choice of the material to be preferably selected for the planarization regions 110 further widens.

As the material of the planarization regions 110, a resin material having excellent film forming properties is preferably used. As such a resin, most solvent-soluble resins out of thermoplastic resins, thermosetting resins, and photocuring resins are usable. More specifically, polyphenylene sulfide (PPS), polyalylate (PAR), polysulfone (PSF), polyethersulfone (PES), polyetherimide (PEI), polyamide imide (PAI), polyether ether ketone (PEEK), liquid crystal polyester (LCP), polypropylene (PP), polyvinylidene chloride (PVDC), polyethylene terephthalate (PET), polycarbonate (PC), polytetrafluoroethylene resin (PTFE), melamine formaldehyde resin (MF), phenol formaldehyde resin (PF), epoxy resin (EP), unsaturated polyester resin (UP), and polyvinyl phenol (PVPh) are usable. Out of these resins, polyalylate (PAR), polysulfone (PSF), polyphenylene sulfide (PPS), polyether ether ketone (PEEK), polyimide resin, polytetrafluoroethylene resin, and the like are preferable as more heat-resistant reins having heat-resistant temperatures of 150° C. or more. Polyamide imide (PAI), polyether ether ketone (PEEK), and the like are especially preferable materials in the present invention because they are resistant to a temperature of 250° C. or more and usable for a long time. In addition, polyvinyl phenol (PVPh) capable of forming an ultrathin film without pinholes is also a particularly preferable material in the present invention. The planarization regions 110 can be made of not only a resin but also an inorganic insulating material such as silicon oxide (SiO₂), silicon nitride (Si₃N₄), silicon oxynitride (SiNO), or silicon carbonitride (SiCN).

The gate insulating film 103 needs to be formed by selecting a material and manufacturing process capable of guaranteeing a gate capacitance and leak current prevention. The gate insulating film 103 is preferably made of a heat-resistant material such that high-temperature processing can be performed in processes applied after deposition. Examples of such materials are inorganic insulating material such as silicon oxide (SiO₂), silicon nitride (Si₃N₄), silicon oxynitride (SiNO), and silicon carbonitride (SiCN).

To achieve further micronization and higher performance of an electronic element, the gate insulating film 103 is preferably formed by selecting a material having a higher dielectric constant and good electrical matching (low interface level) to adjacent layers and applying appropriate manufacturing process and manufacturing conditions. Examples of the material are so-called high-k materials, and one of them is preferably selected and used in accordance with the design requirements of an electronic element. Examples of high-k materials are transition metal oxides such as HfO₂ and ZrO₂, silicates thereof (HfSiₓO_{y} and ZrSiₓO_{y}), Al₂O₂, and compound oxides thereof (Hf₁₋ₓAlₓO_{y} and Zr₁₋ₓAlₓO_{y}). In addition, mixed oxides containing multiple elements Si, Hf, Ti, and La, rutile-type TiO₂ (relative dielectric constant: about 80), (Ba, Sr) TiO₃ (perovskite), rare-earth oxides based on SrBi₄Ti₄O₁₅, SrBi₂Ta₂O₉, Ta₂O₃, La₂O₃, Dy₂O₃, and La₂O₃, HfSiON, and the like are also usable.

The gate insulating film 103 may be formed by a stacked structure member made by appropriately selecting two or more materials from those described above and stacking layers of them. Examples of the stacked structure member are two-layer structures such as HfSiON/SiO₂, HfO₂/Al₂O₃, TiO₂/La₂O₃, and HfLaSiO/SiO₂ and three-layer structures such as HfO₂/Y₂O₃/Al₂O₃ and TiO₂/HfSiO/SiO₂.

Most of the above-mentioned materials are preferably used to form the gate insulating film 103 in the present invention because they can largely reduce a leak current in EOT (Equivalent Oxide Thickness) of 1 nm or less.

In the present invention, a film made of an Hf-based material is particularly preferable as the gate insulating film 103. An Hf-based high-k film can shift the effective work function of a metal electrode to a low energy side by adding La. In this method, the content and film thickness distribution of La are important. Hence, film design is preferably done sufficiently considering these points. When the La content is increased, a promising substance similar to an La-based oxide and having a high relative dielectric constant of about 27 can be obtained. However, since an La-based oxide is hygroscopic and reacts with water in atmosphere, considerations need to be given to, for example, employing a multichamber manufacturing process without breaking a vacuum, or in an electronic element forming process, placing the structure in a rare gas atmosphere such as Ar or He.

When adding La, the gate insulating film 103 is preferably formed by co-sputtering using an HfTi target and an HfLa target. At this time, the La content is adjusted by changing the composition ratio of La in the HfLa target as needed. Alternatively, the La content in the gate insulating film 103 can be adjusted by performing deposition while intermittently blocking the HfLa target from plasma.

HfO₂ is a material preferable for the gate insulating film 103 because its dielectric constant can greatly be improved by adding yttrium (Y) or silicon (Si).

A SAM (Self-Assembled Monolayer) may be employed as the gate insulating film 103. In this case, a SAM itself or a multilayer structure of SAMs can be used as the gate insulating film 103. As a multilayer structure of SAMs, for example, a Langmuir film is also usable. Alternatively, a composite stacked structure of a thin Al₂O₃ film and a SAM of n-octadecyl phosphonic acid may be employed.

In the present invention, a preferable material combination for the gate electrode 102 and the gate insulating film 103 can appropriately be selected from the above-described materials. For example, a combination Metal/HfLaSiO/SiO₂ such as Mo/HfSiON/SiO₂ or Mo—O—Hf/HfSiON/SiO₂, a combination TiN/HfSiON, a combination Metal/HfSiO/TiO₂, and a combination TiN/TiO₂/HfSiO are usable.

The interface characteristic between the gate electrode 102 and the gate insulating film 103 largely affects the device (semiconductor element) characteristic. Hence, the gate electrode 102 and the gate insulating film 103 are preferably formed with care and contrivance more than in selecting the materials so as to suppress formation of an interface level that traps carriers or formation of an energy barrier. For example, the gate electrode 102 and the gate insulating film 103 are preferably formed by a multichamber process. Additionally, for example, a TiN/HfSiO structure is preferably formed by a multichamber solid phase interface reaction method. The multichamber solid phase interface reaction method is SPIR (Solid Phase Interface Reaction) based on physical vapor deposition (see H. Watanabe et al., Appl. Phys. Lett. 85, 449, 2004).

The layer region (A) 107 is preferably made of lanthanum boride (lanthanum hexaboride: LaB₆), as described above. Preferably, the layer region (A) 107 is made of nitrogen containing lanthanum boride (LaB₆(N)).

In the present invention, a more preferable LaB₆(N) film employed for the layer region (A) 107 has a crystal structure and contains 0.3 to 0.5 at % of nitrogen atoms. In addition, the ratio of crystals within the grain size range of 10 to 250 nm to all crystals of the film is 20% to 90%, and the degree of crystallinity of the film is 20% or more. More preferably, the peak of the crystal grain size distribution within the grain size range of 10 to 250 nm exists within the range of 15 to 150 nm.

The present inventors assume that setting the above-described numerical ranges probably makes it possible to form an LaB₆ film having not only a work function as small as 2.4 eV but also an excellent interface characteristic and high adhesion derived from good interface affinity to the active layer region 104. For this reason, it is possible to obtain an LaB₆ film capable of maintaining intended adhesion and satisfactory aging resistance properties without causing film rise or peeling even when the cumulative use time of a device is considerably long.

The ratio of crystals within the grain size range of 10 to 250 nm to all crystals of the film falls preferably within the above-described numerical range, more preferably within the range of 50% to 90%, and much more preferably within the range of 80% to 90%. More preferably, the ratio of crystals within the grain size range of 30 to 200 nm falls within the range of 50% to 90%. Especially preferably, the ratio of crystals within the grain size range of 50 to 150 nm falls within the range of 50% to 90%.

In the present invention, to obtain a more excellent nitrogen containing lanthanum boride (LaB₆(N)) film, the degree of crystallinity of the film is also important. The degree of crystallinity is preferably 20% or more, as described above, more preferably 30% or more, and much more preferably 50% or more.

The position of the peak of the crystal grain size distribution is also an important parameter to obtain a more suitable (LaB₆(N)) film of the present invention. In the present invention, the peak of the crystal grain size distribution within the grain size range of 10 to 250 nm exists preferably within the range of 15 to 150 nm, more preferably within the range of 15 to 120 nm, and much more preferably within the range of 20 to 100 nm.

The source electrode portion 105 and the drain electrode portion 106 are preferably made of materials appropriately selected in consideration of the relationship to the material of the active layer region 104 so that an electrically smooth contact with the active layer region 104 can be obtained. More specifically, in the nMOS Tr 100, the active layer region 104 has an n-type operation characteristic. For this reason, a layer region out of the source electrode portion 105, which directly contacts the active layer region 104, is preferably made of a material whose work function is as small as possible. In the present invention, the source electrode portion 105 also has the function of an electrical contact to the outside of the nMOS Tr 100. It is therefore necessary to select the material of at least the uppermost layer region in consideration of matching with the material of an external electrical contact.

In the nMOS Tr 100 shown in FIG. 1, the source electrode portion 105 has a stacked structure of, for example, an upper electrode region 105a made of a material inexpensive and easy to handle and a lower electrode region 105b made of a material having a small work function. In the present invention, to form an electrically smooth contact between the upper electrode region 105a and the active layer region 104, the lower electrode region 105b has a multilayer structure, and layer regions are sequentially made of materials having work functions close to that of the material of the active layer region 104 from a lowermost layer region (MUDL) in direct contact with the active layer region 104 to an uppermost layer region (MUPL) (the entire stacked structure of these layer regions will also be referred to as a “transition layer” hereinafter).

For example, when the active layer region 104 is made of pentacene and has an n-type operation characteristic, the material of the lowermost layer region (MUDL) is preferably appropriately selected so as to ensure matching with the LUMO (Lowest Unoccupied Molecular Orbital) (3.2 eV) of pentacene as much as possible. This facilitates electron injection from the source electrode portion 105 to the LUMO of the material of the active layer region 104.

More specifically, for example, the upper electrode region 105a is made of a metal such as Al or Cu, and the lowermost layer region (MUDL) of the lower electrode region 105b is made of a material having a small work function such as lanthanum boride. The lowermost layer region (MUDL) of the lower electrode region 105b is preferably made of LaB₆(N) having the above-described characteristic. The lowermost layer region (MUDL) is particularly preferably made of the same material as that described as LaB₆(N) of the layer region (A) 107.

As materials having small work functions used in the present invention, materials having work functions of 3 eV or less are preferably selected. Detailed examples of materials having small work functions preferably used in the present invention are barium (Ba), LaB₆, CeB₆, W—Cs, W—Ba, W—O—Cs, W—O—Ba, and 12CaO.7Al₂O₃(C12A7) electride. Especially, LaB₆ containing N (nitrogen) is a preferable material because of its excellent chemical stability. A more preferable material is LaB₆ (2.4 eV) containing nitrogen in about 0.4%.

A detailed example of the lower electrode region 105b formed as a transition layer having a six-layer structure will be described below. As the first example, for example, the lowermost layer region (MUDL) is made of N (nitrogen) containing LaB₆ (“LaB₆(N)”) (2.4 eV), and the upper electrode region 105a is made of aluminum (Al) (4.28 eV). In this case, the transition layer can have the following six-layer structure as a preferable example. That is, sequentially from the side of the lowermost layer region (MUDL) (lowermost transition layer) made of LaB₆(N), the six-layer structure includes an LaB₆(N) layer (lowermost transition layer), an Sm or Pr (2.7 eV) layer (first intermediate transition layer), an Er (3.1 eV) layer (second intermediate transition layer), an La (3.5 eV) laser (third intermediate transition layer), an Hf (3.8 eV) layer (fourth intermediate transition layer), and a Zr (4.1 eV) layer (uppermost transition layer).

As the second example, for example, the lowermost layer region (MUDL) is made of N (nitrogen) containing LaB₆ (“LaB₆(N)”) (2.4 eV), and the upper electrode region 105a is made of copper (Cu) (4.6 eV). In this case, the transition layer can have the following eight-layer structure as a preferable example. That is, sequentially from the side of the lowermost layer region (MUDL) (lowermost transition layer), the seven-layer structure includes an LaB₆(N) layer (lowermost transition layer), an Sm or Pr (2.7 eV) layer (first intermediate transition layer), an Er (3.1 eV) layer (second intermediate transition layer), an La (3.5 eV) laser (third intermediate transition layer), an Hf (3.8 eV) layer (fourth intermediate transition layer), a Zr (4.1 eV) layer (fifth intermediate transition layer), an Al (4.3 eV) layer (sixth intermediate transition layer), and a copper (Cu) (4.6 eV) layer (uppermost transition layer).

In the drain electrode portion 106, for example, an upper electrode region 106a is made of Al, and a lower electrode region 106b is made of Ni, preferably.

A CMOS semiconductor device (to be described later) uses an organic semiconductor element having a p-type operation characteristic as well. Hence, the materials of the source electrode portion and the drain electrode portion in that case are preferably appropriately selected from the following viewpoint. That is, when the active layer region 104 is made of an organic semiconductor material and has a p-type operation characteristic, materials are appropriately selected so as to ensure energy level matching with the HOMO (Highest Occupied Molecular Orbital) (5.0 eV in pentacene) of the organic semiconductor material as much as possible.

In the present invention, when forming films using organic materials, various film forming methods are employed in accordance with the characteristic and application purpose of an electronic element to be formed and employed deposition materials. Examples of the film forming methods that can be employed in the present invention are an application method, vacuum deposition, CVD (Chemical Vapor Deposition), and PCVD (Plasma Chemical Vapor Deposition). Examples of the application method are spin coating, casting, and printing. Examples of printing are offset printing, letterpress printing, intaglio printing, gravure printing, screen printing, inkjet printing, and micro contact printing. For a definition of 10 μm or less, inkjet printing and micro contact printing are preferably used. Especially in an organic TFT, the switching characteristic of the element is known to be improved by decreasing the interval (channel length: L) between the source electrode and the drain electrode. Hence, micro contact printing capable of large-area patterning on a submicron order is preferably employed.

An nMOS Tr of a bottom gate type has been explained with reference to FIG. 1. However, the present invention is not limited to this and is applicable to any electronic element as long as the electron supply layer provided in direct contact with the active layer region is made of lanthanum boride. For example, the present invention can also be applied to an nMOS Tr of a top gate type.

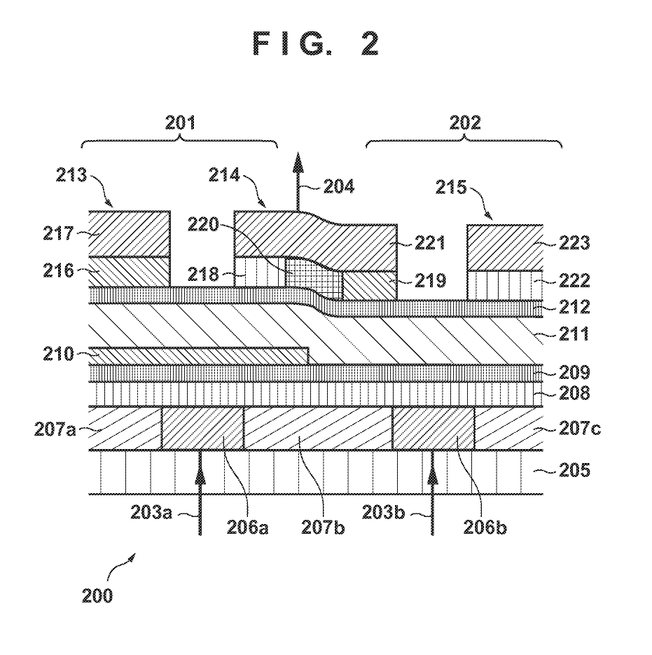

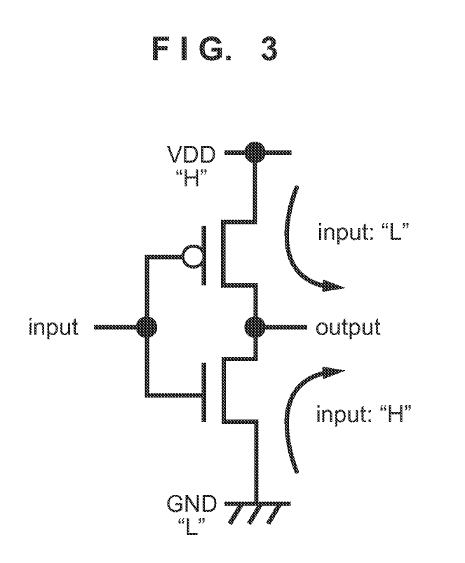

FIG. 2 is a schematic structural explanatory view for explaining the structure of a semiconductor device having a CMOS circuit structure as one of examples of preferable embodiments of the present invention. FIG. 3 is a circuit diagram of the semiconductor device shown in FIG. 2.

A CMOS semiconductor device 200 includes an nMOS Tr 201 and a pMOS Tr 202. The nMOS Tr 201 has the same arrangement as the nMOS Tr 100 shown in FIG. 1.

The CMOS semiconductor device 200 includes input terminals 203a and 203b and an output terminal 204. The input terminals 203a and 203b are connected on the input upstream side, as shown in FIG. 3.

In the CMOS semiconductor device 200 shown in FIG. 2, when a signal of “L” level is input, the nMOS Tr 201 operates, and when a signal of “H” level is input, the pMOS Tr 202 operates.

Gate electrodes 206a and 206b, a gate insulating film 208, a first common interface control layer 209, an electron supply layer region 210, a common active layer region 211, a second common interface control layer 212, source electrode portions 213 and 215, and a common drain electrode portion 214 are overlaid on a substrate 205. The first common interface control layer 209 and the second common interface control layer 212 are provided in an example of a more preferable embodiment, and need not always be provided if the interface to the common active layer region 211 has a sufficient characteristic in element design.

The electron supply layer region 210 is provided only on the side of the nMOS Tr 201, as shown in FIG. 2, and supplies electrons to the active layer region of the common active layer region 211 on the side of the nMOS Tr 201. The electron supply layer region 210 is the same as the layer region (A) 107 and is formed using the same material and manufacturing method as described for the layer region (A) 107.

Planarization regions 207a, 207b, and 207c are provided on the sides of the gate electrodes 206a and 206b, as in FIG. 1.

The source electrode portion 213 is almost the same as the source electrode portion 105 shown in FIG. 1. An upper electrode region 217 is almost the same as the upper electrode region 105a, and a lower electrode region 216 is almost the same as the lower electrode region 105b. The source electrode portion 215 is almost the same as the drain electrode portion 106 shown in FIG. 1. An upper electrode region 223 is almost the same as the upper electrode region 106a, and a lower electrode region 222 is almost the same as the lower electrode region 106b.

The drain electrode portion 214 is provided with a structure that partially structurally isolates the drain electrode portion of the nMOS Tr 201 and that of the pMOS Tr 202 from each other. More specifically, a lower electrode region 218 of the drain electrode portion of the nMOS Tr 201 and a lower electrode region 219 of the drain electrode portion of the pMOS Tr 202 are electrically spatially isolated by an isolation region 220.

The lower electrode region 218 is made of, for example, Ni, like the lower electrode region 106b. The lower electrode region 219 is made of a material having a small work function, for example, lanthanum boride, like the lower electrode region 105b. In particular, the lower electrode region 219 is preferably made of LaB₆(N) having the above-described characteristic. An upper electrode region 221 is made of a metal such as Al, like the upper electrode region 106a. The common active layer region 211 is the same as the active layer region 104 and is formed using the same material and manufacturing method as described for the active layer region 104.

The substrate 205 is the same as the substrate 101. The gate insulating film 208 is the same as the gate insulating film 103. The gate electrodes 206a and 206b are the same as the gate electrode 102. The first common interface control layer 209 and the second common interface control layer 212 are the same as the first interface control layer 108 and the second interface control layer 109, respectively.

The present invention is not limited to the above embodiments and various changes and modifications can be made within the spirit and scope of the present invention. Therefore, to apprise the public of the scope of the present invention, the following claims are made.

### REFERENCE SIGNS LIST

100 . . . nMOS Tr
101, 205 . . . substrate
102, 206 . . . gate electrode
103, 208 . . . gate insulating film
104 . . . active layer region
105, 213, 215 . . . source electrode portion
106, 214 . . . drain electrode portion
107, 210 . . . electron supply layer region
108, 109, 209, 212 . . . interface control layer
110, 207 . . . planarization region
200 . . . CMOS semiconductor device
201 . . . nMOS Tr
202 . . . pMOS Tr
203 . . . input terminal
204 . . . output terminal
211 . . . common active layer region
216, 218, 219, 222 . . . lower electrode region
217, 221, 223 . . . upper electrode region
220 . . . isolation region

1. An organic semiconductor element comprising:
a source electrode portion;
a drain electrode portion;
an active layer region of an organic semiconductor;
a gate insulating film; and
a gate electrode portion, wherein
the source electrode portion has a multilayer structure including a first layer region arranged on the active layer region contacting the active layer region, and a second layer region arranged above the first layer region so as not to contact the active layer region, and
a work function difference between a material of the first layer region and a material of the active layer region is smaller than a work function difference between the material of the active layer region and a material of the second layer region.

2-9. (canceled)

10. The organic semiconductor element according to claim 1, wherein the organic semiconductor element exhibits an n-type operation characteristic.

11. A CMIS semiconductor device having a CMIS circuit arrangement, wherein an electronic element with an n-type operation characteristic included in the CMIS circuit is the organic semiconductor element according to claim 10.

12. An organic semiconductor element comprising:
a source electrode portion;
a drain electrode portion;
an active layer region of an organic semiconductor comprising pentacene;
a gate insulating film;
a gate electrode portion; and
a layer region arranged between said active layer region and the gate insulating film so as to contact said active layer region, wherein
the source electrode portion has a multilayer structure including a first layer region arranged on the active layer region contacting the active layer region, and a second layer region arranged above the first layer region so as not to contact the active layer region,
a work function difference between a material of the first layer region and a material of the active layer region is smaller than a work function difference between the material of the active layer region and a material of the second layer region.

13. The organic semiconductor element according to claim 12, wherein the first layer region comprises lanthanum boride (LaB₆) and nitrogen.

14. The organic semiconductor element according to claim 12, wherein the organic semiconductor element exhibits an n-type operation characteristic.

15. A CMIS semiconductor device having a CMIS circuit arrangement, wherein an electronic element with an n-type operation characteristic included in the CMIS circuit is the organic semiconductor element according to claim 14.

16. An organic semiconductor element comprising:
a source electrode portion;
a drain electrode portion;
an active layer region of an organic semiconductor;
a gate insulating film; and
a gate electrode portion, wherein
the drain electrode portion has a multilayer structure including a third layer region arranged on the active layer region contacting the active layer region, and a fourth layer region arranged above the third layer region so as not to contact the active layer region,
a work function difference between a material of the third layer region and a material of the active layer region is smaller than a work function difference between the material of the active layer region and a material of the fourth layer region, and
the organic semiconductor exhibits a p-type operation characteristic.

17. The organic semiconductor element according to claim 1, wherein the first layer region comprises lanthanum boride (LaB₆) and nitrogen.

18. The organic semiconductor element according to claim 12, wherein the layer region arranged between said active layer region and the gate insulating film comprises lanthanum boride (LaB₆) and nitrogen.

19. The organic semiconductor element according to claim 16, wherein the third layer region comprises lanthanum boride (LaB₆) and nitrogen.

20. The organic semiconductor element according to claim 1, wherein the drain electrode portion has a multilayer structure including a third layer region arranged on the active layer region contacting the active layer region, and a fourth layer region arranged above the third layer region so as not to contact the active layer region, and
the third layer region of the drain electrode portion is made of a different material than the first layer region of the source electrode portion.

21. The organic semiconductor element according to claim 12, wherein the drain electrode portion has a multilayer structure including a third layer region arranged on the active layer region contacting the active layer region, and a fourth layer region arranged above the third layer region so as not to contact the active layer region, and
the third layer region of the drain electrode portion is made of a different material than the first layer region of the source electrode portion.

22. The organic semiconductor element according to claim 16, wherein the source electrode portion has a multilayer structure including a first layer region arranged on the active layer region contacting the active layer region, and a second layer region arranged above the first layer region so as not to contact the active layer region, and
the first layer region of the source electrode portion is made of a different material than the third layer region of the drain electrode portion.
